(19) United States
(12) Patent Application Publication
(10) Pub. No.: US 2024/0021563 A1
(43) Pub. Date: Jan. 18, 2024

(54) METHOD OF MANUFACTURING A STACKED SEMICONDUCTOR PACKAGE

(71) Applicant: SAMSUNG ELECTRONICS CO., LTD., Suwon-si (KR)

(72) Inventor: Seokhyun Lee, Suwon-si (KR)

(21) Appl. No.: 18/351,748

(22) Filed: Jul. 13, 2023

(30) Foreign Application Priority Data
Jul. 14, 2022 (KR) 10-2022-0087074

(51) Int. Cl. H01L 23/00; H01L 25/065; H01L 25/00

(52) U.S. Cl. CPC H01L 24/27; H01L 25/0657; H01L 25/50; H01L 24/48; H01L 24/32; H01L 2225/06506; H01L 2224/48105; H01L 2224/48145; H01L 2224/48227; H01L 2224/27416; H01L 2224/27515; H01L 2224/32145; H01L 2224/32225; H01L 2924/2021

(57) ABSTRACT

A method of manufacturing a semiconductor package includes preparing a wafer having a first surface on which a plurality of semiconductor chips are disposed and a second surface, opposite to the first surface. The second surface of the wafer is ground. The ground second surface of the wafer is coated with a liquid adhesive material to form an uncured adhesive layer having a thickness of 5 μm or less. The uncured adhesive layer on the wafer is semi-cured. The wafer is cut so as to separate the plurality of semiconductor chips from one another. The plurality of semiconductor chips are stacked using the semi-cured adhesive layer. The semi-cured adhesive layer disposed between the plurality of stacked semiconductor chips is fully cured.

### CROSS-REFERENCE TO RELATED APPLICATION(S)

This application claims priority to Korean Patent Application No. 10-2022-0087074, filed on Jul. 14, 2022 in the Korean Intellectual Property Office, the disclosure of which is herein incorporated by reference in its entirety.

### TECHNICAL FIELD

The present inventive concept relates to a semiconductor package and, more specifically, to a method of manufacturing a stacked semiconductor package.

### DISCUSSION OF THE RELATED ART

Recently, demand for high capacity, thinness, and miniaturization of semiconductor devices and electronic products using the same has increased, and there have been a variety of related package technologies employed to achieve this goal. For example, a high density chip package can be implemented by vertically stacking various semiconductor chips. This package technology may integrate semiconductor chips having various functions in a smaller area than a general package including one semiconductor chip; however, since an adhesive film having a predetermined thickness is used between the semiconductor chips of the stack, a thickness of the package is increased due to the adhesive film as the number of stacked chips within the package increases.

### SUMMARY

A method of manufacturing a semiconductor package includes preparing a wafer having a first surface on which a plurality of semiconductor chips are formed and a second surface, opposite to the first surface. The second surface of the wafer is ground. The ground second surface of the wafer is coated with a liquid adhesive material to form an uncured adhesive layer having a thickness of 5 μm or less. The uncured adhesive layer on the wafer is semi-cured. The wafer is cut so as to separate the plurality of semiconductor chips from one another. The plurality of semiconductor chips are stacked using the semi-cured adhesive layer. The semi-cured adhesive layer disposed between the plurality of stacked semiconductor chips is fully cured.

A method of manufacturing a semiconductor package includes preparing a wafer having a first surface on which a plurality of semiconductor chips are formed and a second surface, opposite to the first surface. The second surface of the wafer is coated with a liquid adhesive material in the range of 10 cP to 2000 cP to form an uncured adhesive layer having a thickness of 5 μm or less. The uncured adhesive layer is semi-cured by applying a first type of energy to the wafer. The wafer is cut so as to separate the plurality of semiconductor chips from one another. The plurality of semiconductor chips are stacked using the semi-cured adhesive layer. The semi-cured adhesive layer disposed between the plurality of stacked semiconductor chips is fully cured by applying a second type of energy.

A method of manufacturing a semiconductor package includes preparing a wafer having a first surface on which a plurality of semiconductor chips are formed and a second surface, opposite to the first surface. The second surface of the wafer is coated with a liquid adhesive material including an ultraviolet (UV) curable composition and a thermo-curable composition to form an uncured adhesive layer. The uncured adhesive layer is semi-cured by applying any one of ultraviolet light and heat to the wafer. The wafer is cut to separate the plurality of semiconductor chips from one another. The plurality of semiconductor chips are stacked using the semi-cured adhesive layer. The semi-cured adhesive layer disposed between the plurality of stacked semiconductor chips is fully cured by applying the other of ultraviolet light and heat.

### BRIEF DESCRIPTION OF DRAWINGS

The above and other aspects, and features of the present inventive concept will be more clearly understood from the following detailed description, taken in conjunction with the accompanying drawings, in which:

FIG. 1 is a perspective view illustrating a semiconductor package according to an embodiment of the present inventive concept;

FIG. 2 is a side cross-sectional view illustrating the semiconductor package of FIG. 1;

FIG. 3 is a partially enlarged view of a junction region of the semiconductor package of FIG. 2;

FIGS. 4A to 4E are cross-sectional views illustrating major processes (e.g., manufacturing a semiconductor chip) of a method of manufacturing a semiconductor package according to an embodiment of the present inventive concept;

FIG. 5 is a graph illustrating the coating thickness of the adhesive material according to the viscosity;

FIG. 6 is a graph illustrating a thickness variation according to a position of a wafer;

FIGS. 7A and 7B are cross-sectional views illustrating major processes (e.g., a chip stacking process) of a method of manufacturing a semiconductor package according to an embodiment of the present inventive concept;

FIG. 8 is a graph illustrating a change in a state of an adhesive layer during a process of manufacturing a semiconductor chip and semiconductor package;

FIG. 9 is a schematic diagram illustrating changes in a reactor through primary and secondary curing processes employed in a process of manufacturing a semiconductor package according to an embodiment of the present inventive concept; and

FIGS. 10 and 11 are side cross-sectional views illustrating semiconductor packages according to various embodiments of the present inventive concept.

### DETAILED DESCRIPTION

Hereinafter, example embodiments of the present inventive concept will be described with reference to the accompanying drawings.

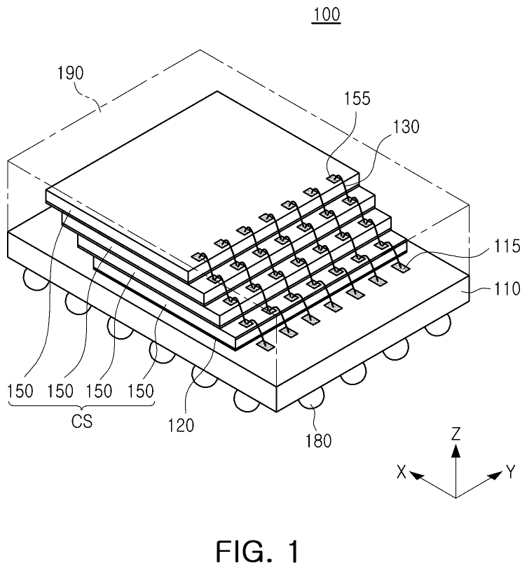

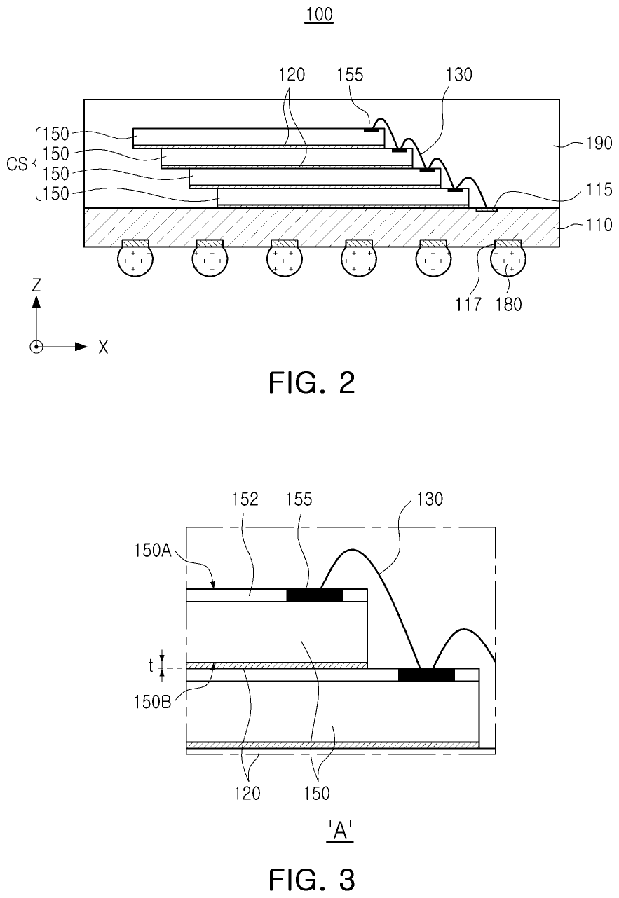

FIG. 1 is a perspective view illustrating a semiconductor package according to an embodiment of the present inventive concept, and FIG. 2 is a side cross-sectional view illustrating the semiconductor package of FIG. 1.

Referring to FIGS. 1 and 2, the semiconductor package 100, according to an embodiment, may include a package substrate 110, a chip stack CS disposed on the package substrate, and a molding portion 190 at least partially covering the chip stack CS on the package substrate 110.

The package substrate 110 may include, for example, a printed circuit board (PCB), a flexible board, a tape board, and/or the like. The package substrate 110 may include upper pads 115 disposed on an upper surface of the package substrate 110 and lower pads 117 disposed on a lower surface of the package substrate 110. External connection terminals 180 configured to electrically connect an external device to the semiconductor package 100 may be disposed on the lower pads 117. The external connection terminals 180 may be, for example, a solder ball and/or a conductive pillar.

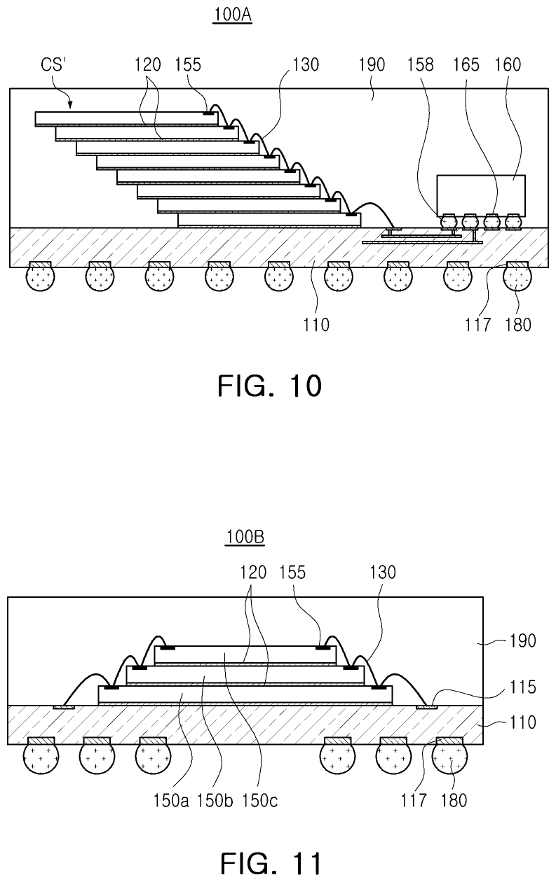

The chip stack CS may include a plurality of semiconductor chips 150 stacked on the package substrate 110 in a vertical direction (e.g., a Z-direction). In the present embodiment, the chip stack CS is illustrated as including four semiconductor chips 150 stacked in a vertical direction, but is not necessarily limited thereto. In some embodiments, the chip stack CS may include two, three, or five or more semiconductor chips 110 (e.g., refer to FIGS. 10 and 11).

The plurality of semiconductor chips 150 constituting the chip stack CS may each be the same type of semiconductor chips. For example, the plurality of semiconductor chips 150 may be memory semiconductor chips. The memory chips may include a flash memory, for example, a NAND flash memory. In some embodiments, the memory chip may be a volatile memory semiconductor chip, such as dynamic random access memory (DRAM) or static random access memory (SRAM) or a nonvolatile memory semiconductor chip, such as phase-change random access memory (PRAM), magneto-resistive random access memory (MRAM), ferroelectric random access memory (FeRAM) or resistive random access memory (RRAM). In some other embodiments, the plurality of semiconductor chips 150 constituting the chip stack CS may include different types of semiconductor chips. For example, some of the plurality of semiconductors may be logic chips, and a remainder thereof may be memory chips. For example, the logic chip may be a central processing unit (CPU) chip, a graphics processing unit (GPU) chip, or an application processor (AP) chip.

In the present embodiment, each semiconductor chip 150 may include chip pads 155 disposed adjacent to one edge of each semiconductor chip 150 and arranged along the one edge. For example, the chip pads 155 of each semiconductor chip 150 may be arranged in a second direction (e.g., a Y-direction). The chip pads 155 may be electrically connected to an integrated circuit (IC) provided in each semiconductor chip 150. For example, the IC may include a memory circuit or a logic circuit. As shown in FIG. 3, such an IC may be provided as a device layer 152 located on an upper surface 150A (or an active surface) of the semiconductor chip 150. The device layer 152 may include devices (e.g., transistors) formed on the active surface of the semiconductor chip 150 and a wiring layer connected to the devices.

In the present embodiment, the plurality of semiconductor chips 150 may have the same dimension. For example, a horizontal width, a vertical width, and a thickness of the plurality of semiconductor chips 150 may be the same. Also, the plurality of semiconductor chips 150 may have the same pad arrangement. For example, in each of the plurality of semiconductor chips, the number of chip pads included in each semiconductor chip, an arrangement order of the chip pads, a size of the chip pads, a spacing between the chip pads, etc. may be the same. In some embodiments, the plurality of semiconductor chips 150 may include one or more semiconductor chips having different dimensions or different chip arrangements.

The plurality of semiconductor chips 150 may be sequentially offset to be stacked in the first direction (e.g., the X-direction) to configure the chip stack CS. For example, one semiconductor chip 150 may be stacked on the other semiconductor chip 150 such that a portion thereof protrudes in the first direction (e.g., the X-direction) from the other semiconductor chip 150 disposed therebelow. For example, the plurality of semiconductor chips 150 may be stacked in a stepwise fashion. Due to the offset, the chip pads 155 respectively included in the plurality of semiconductor chips 150 may be exposed. The chip channel pads 155 of the semiconductor chips 150 disposed on different layers may be electrically connected by wires 130. Also, the chip channel pad 155 of the lowermost semiconductor chip 150 among the semiconductor chips 150 and the upper pad 115 of the package substrate 110 may be electrically connected by the wire 130. These wires 130 may be formed through a wire bonding process, and may be conductive wires including a conductive material, such as gold (Au) or copper (Cu).

An adhesive layer 120 may be provided on a lower surface of each semiconductor chip 150, and may be stacked on the semiconductor chip 150 disposed therebelow using the adhesive layer 120. The lowest semiconductor chip among the semiconductor chips 110 may be attached to an upper surface of the package substrate 130 through the adhesive layer 120.

FIG. 3 is a partially enlarged view of a junction region of the semiconductor package of FIG. 2.

Referring to FIG. 3 together with FIG. 2, the adhesive layer 120 employed in the present embodiment may be directly coated on a lower surface 150B (e.g., on the rear surface of the wafer) of the semiconductor chip 150, unlike the conventional film type. A film-type adhesive, such as a die attach film, may be manufactured to have a predetermined thickness in advance and then attached to the wafer to be used. In particular, since the film-type adhesive should be able to be handled by a series of processes, such as an attachment process, it is difficult to implement the adhesive to become ultra-thin (e.g., 5 μm or less). In contrast, since the adhesive layer 120 employed in the present embodiment is formed by a coating process, such as spin coating, directly on a rear surface of the wafer on which a plurality of chips are implemented with a liquid adhesive material, the adhesive layer 120 may be easily implemented to be ultra-thin.

A thickness “t” of the adhesive layer 120, according to the present embodiment, may be 5 μm or less. In some embodiments, the thickness “t” of the adhesive layer 120 may be 3 μm or less. Since the adhesive layer 120 is provided on a lower surface 150B of all semiconductor chips 150, a large reduction in package size may be expected depending on a total number of stacks only by reducing the thickness “t” of the adhesive layer 120. For example, in a stack of four semiconductor chips 150 as in the present embodiment, when the thickness of each adhesive layer is implemented as 3 μm, an effect of reducing the height (or thickness) of the package of 7×4 μm, for example, 28 μm, may be expected, compared to the case of using a conventional DAF having a thickness of 10 μm. This reduction effect may be expected to increase as the number of stacks increases.

The adhesive layer 120, according to the present embodiment, may be obtained through a primary curing process after coating on the rear surface of the wafer and a secondary curing process after the chip stack. Through these curing processes, the modulus of the adhesive material may be increased. The primary curing process may be performed as a partial curing process for forming a semi-cured (e.g., B-stage) adhesive layer on the wafer surface, and the secondary curing process may be performed as a full curing process to obtain a final adhesive layer 120 between the stacked semiconductor chips 150.

As discussed herein, the term “semi-cured” is intended to mean performing a curing process on an uncured curable material but stopping the curing process prior to completion thereof (e.g., performing the curing process and then ending the curing process at a point in which further curing is possible). In contrast, the term “fully cured” is intended to mean that a curing process has been performed to completion, for example, so that no further curing is possible. For example, where curing is defined by the cross-linking of polymers, semi-curing is performed prior to all polymers being cross-linked and fully curing is performed until all polymers are cross-linked.

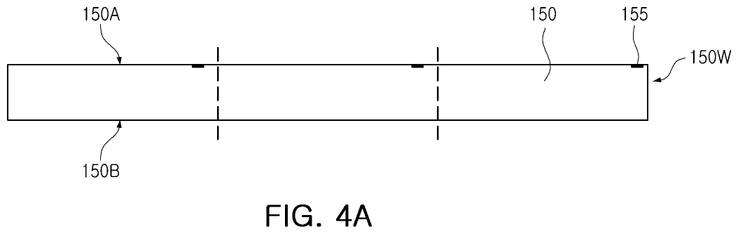

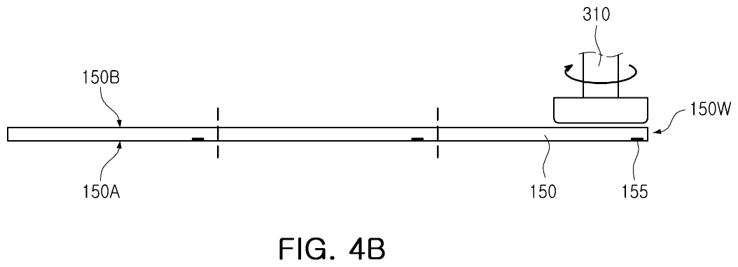

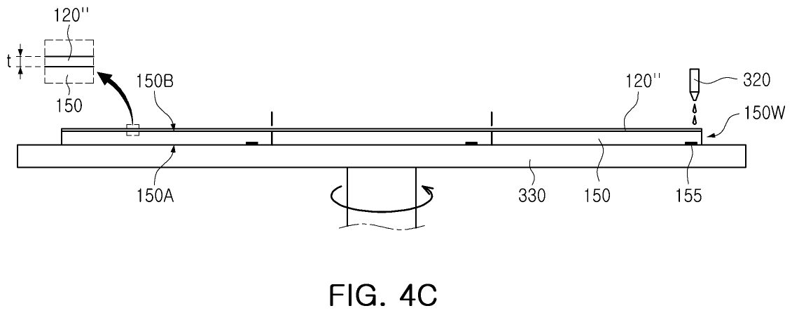

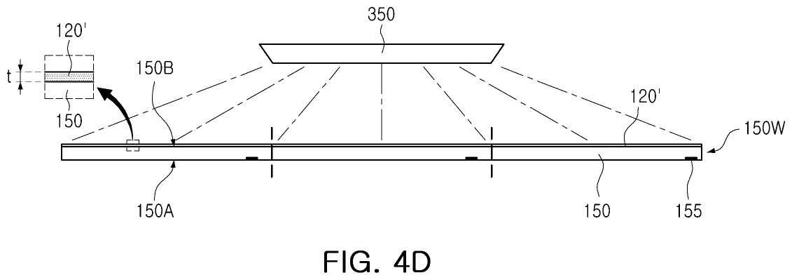

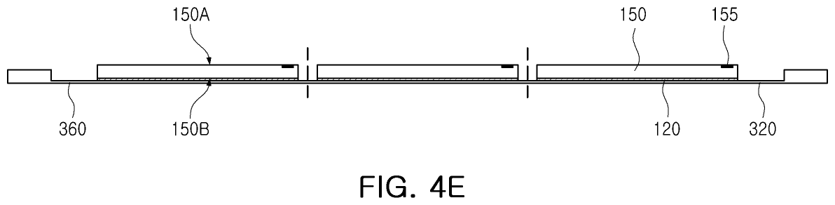

The adhesive layer 120, according to the present embodiment, may be a result of curing different types of energy curable compositions. For example, the liquid adhesive material for the adhesive layer 120 may include different types of energy curable compositions. The liquid adhesive material may provide the adhesive layer 120 for the chip stack through primary and secondary curing processes in which different types of energy are applied. In some embodiments, the liquid adhesive material includes a photo-curable composition and a thermo-curable composition, the primary curing process may be performed using light and/or thermal energy (i.e., heat), and the secondary curing process may be performed using light and/or thermal energy to obtain a semi-cured adhesive layer on the wafer surface. A detailed adhesive layer forming process will be described later with reference to FIGS. 4A to 9.

The semiconductor package 100 may include a molding portion 190 at least partially covering the chip stack CS on the package substrate 110. For example, the molding portion 190 may cover the upper surface of the package substrate 110 and cover side surfaces of the semiconductor chip 150 included in the chip stack CS. For example, the molding portion 190 may include an insulating resin and/or an epoxy molding compound (EMC).

FIGS. 4A to 4E are cross-sectional views illustrating major processes (e.g., manufacturing a semiconductor chip) of a method of manufacturing a semiconductor package according to an embodiment of the present inventive concept.

Referring to FIG. 4A, a wafer W having a first surface 150A on which a plurality of semiconductor chips 150 are formed and a second surface 150B opposite to the first surface 150A is prepared.

The first surface 150A of the wafer 150W may be an active surface on which a device layer (e.g., 152 of FIG. 3) for the semiconductor chip 150 is formed. The second surface 150B opposite to the first surface 150A may be an inactive surface. The device layer may include devices (e.g., transistors) formed in an active region of the active surface and a wiring layer connected to the devices. Also, chip pads 155 electrically connected to the device layer may be formed in regions corresponding to the semiconductor chips 150, respectively. Such a semiconductor chip may be a flash memory, for example, a NAND flash memory, but is not necessarily limited thereto, and as described above, the semiconductor chip may include another memory chip or a logic chip.

Next, referring to FIG. 4B, the second surface 150B of the wafer 150W may be ground.

The grinding process may be performed by grinding the second surface 150B of the wafer 150W using a grinding machine 310. Through this process, the thickness of the wafer 150W may be reduced. By reducing the thickness, the package may become thinner. However, there is a limit to reducing the thickness of the wafer 150W. For example, if the strength of the semiconductor chip is lowered due to excessive reduction in the thickness of the semiconductor chip 150, the semiconductor chip may be mechanically damaged during the package manufacturing process, so there is a limit to the reduction in the thickness of the wafer. Therefore, exemplary embodiments of the present disclosure provide a method to reduce the thickness of a conventional film-type adhesive layer used as an adhesive disposed between semiconductor chips, and proposes a method of directly coating the second surface 150B of the wafer 150W using a liquid adhesive material, which is a subsequent process.

Referring to FIG. 4C, an uncured adhesive layer 120″ may be formed by coating the ground second surface 150B of the wafer 150W with a liquid adhesive material LA.

The uncured adhesive layer formed in this process may have a thickness that is thinner than that of a conventional film-type adhesive (e.g., DAF). This process may be performed by a spin-coating method. For example, the spin-coating may be performed by placing the wafer 150W on a spin coater 330 and rotating the spin coater 330, while supplying the liquid adhesive material LA to the second surface 150B of the wafer 150W by using a nozzle 320.

As described above, the conventional film-type adhesive has a thickness that may be handled by a series of processes, such as an attachment process, so there is a limit to thinning, whereas the uncured adhesive layer 120″ is directly coated on the second surface 150B of the wafer 150W, so the uncured adhesive layer 120″ may be implemented to have a thickness t0 which is sufficiently thin. For example, the thickness t0 of the uncured adhesive film 120″ may be 5 μm or less. The reduction of the thickness may be additionally controlled by adjusting not only the conditions of spin-coating but also the physical properties, particularly, viscosity, of the liquid adhesive material LA. For example, when the liquid adhesive material LA has a viscosity of 2000 cP, a thickness t0 of the uncured adhesive film 120″ may be 5 μm.

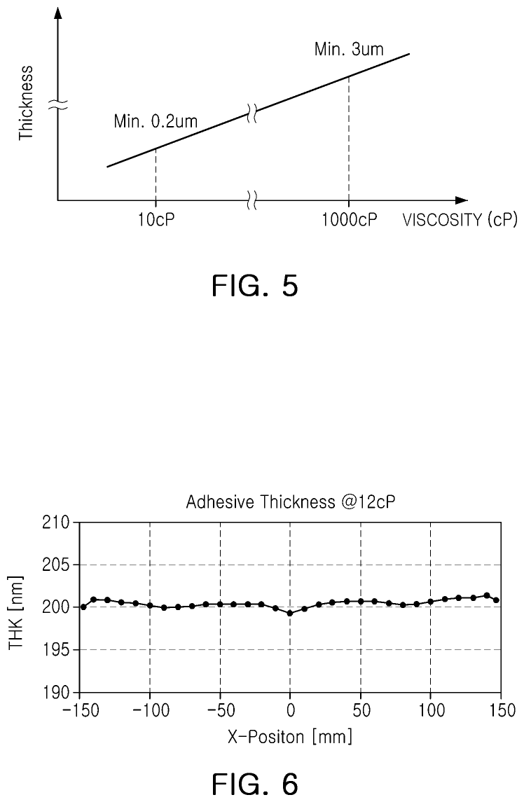

FIG. 5 is a graph illustrating a coating thickness of an adhesive material according to viscosity.

Referring to FIG. 5, the liquid adhesive material LA exhibits an average thickness of the uncured adhesive layer 120″ in a viscosity range of 10 cP to 1000 cP. When the liquid adhesive material has 10 cP, an average thickness of the uncured adhesive layer 120″ is 0.2 μm, and when the liquid adhesive material LA has 1000 cP, the average thickness of the uncured adhesive layer 120″ is 3 μm. As such, the average thickness of the coated uncured adhesive layer 120″ may be thinned to be 3 μm or less, and further down to a level of 0.2 μm according to viscosity.

In addition, in the case of using direct coating using the liquid adhesive material LA, a thickness variation of the adhesive layer 120″ may be guaranteed. For example, in the case of coating the adhesive layer 120″ having at thickness of 5 μm using the liquid adhesive material LA having a viscosity of 2000 cP, the thickness variation may be realized within 0.5 μm. This thickness variation may be significantly lowered in the ultra-thin adhesive layer 120″ using a low viscosity.

FIG. 6 is a graph illustrating a thickness variation according to a position of a wafer.

Referring to FIG. 6, a thickness distribution in one direction on the wafer 150W in the case of coating the uncured adhesive layer 120″ having a thickness of about 0.2 μm using a liquid adhesive material LA having a viscosity of 12 cP is shown. A thickness variation of the ultra-thin, 0.2 μm-thick adhesive layer 120″ was 2.4 nm, which was coated flatly to a fairly high level.

As such, the thickness variation of the uncured adhesive layer 120″ is 10% or less of the average thickness thereof. In particular, the adhesive layer 120″ having higher flatness with a reduced thickness variation may be provided as the thickness of the adhesive layer 120″ decreases.

The liquid adhesive material LA employed in the present embodiment may include different types of energy curable compositions. As such, by combining materials with different curability (e.g., photo-curability and thermo-curability) that respond to different types of energy, a primary curing process after coating on the second surface 150B of the wafer 150W and the secondary curing process after chip stacking may be easily separately performed. For example, the liquid adhesive material LA may be an adhesive material in which a photo-curable composition and a thermo-curable composition are mixed. The photo-curable composition may be configured to be cured by ultraviolet (UV) light. For example, the photo-curable composition may include an acrylic compound and a photoinitiator.

In addition, the photo-curable composition may include a material that is not cured at a hot pressing temperature applied to the chip stack, but is cured at a temperature higher than the hot pressing temperature (e.g., in the range of 100° C. to 150° C.). For example, the photo-curable composition may include an epoxy-based compound, a thermosetting agent, and a curing accelerator.

Referring to FIG. 4D, a semi-cured adhesive layer 120′ may be obtained by applying the primary curing process to the uncured adhesive layer 120″.

Through the primary curing process, the semi-cured adhesive layer 120′ has an increased modulus while attached to the second surface 150B of the wafer 150W to maintain a constant film shape (e.g., ultra-thin film). The semi-cured adhesive layer 120′ obtained in this process may be a B-stage.

As described above, when the liquid adhesive material LA includes different types of energy curable compositions, it may be a semi-cured adhesive layer 120′ obtained by applying a type of energy to cure a curable portion.

In the present embodiment, the liquid adhesive material LA may be an adhesive material in which a photo (e.g., ultraviolet ray)-curable composition and a thermo-curable composition are mixed, and the primary curing process may be performed by applying ultraviolet light using an ultraviolet light source 350. By curing the UV curable composition portion, the uncured adhesive layer 120″ may be changed into the semi-cured adhesive layer 120′. Since the adhesive layer to be irradiated in this process is exposed without a structure for blocking light, the UV curing process may be easily applied.

Next, referring to FIG. 4E, the wafer 150W is cut to prepare a plurality of semiconductor chips 150.

After the wafer 150 is attached to the support tape 360 so that the semi-cured adhesive layer 120′ and the support tape 360 face each other, a cutting process may be performed thereon to separate the wafer 150 into individual chips 150. Each of the plurality of semiconductor chips 150 has the semi-cured adhesive layer 120′ on a lower surface thereof, and since the semi-cured adhesive layer 120′ is not conventional but is directly coated to be implemented as an ultra-thin type, thereby having a thickness of 5 μm or less. Since the semi-cured adhesive layer 120′ is in a semi-cured state, the semi-cured adhesive layer 120′ may have a constant adhesiveness similar to that of a conventional DAF before curing.

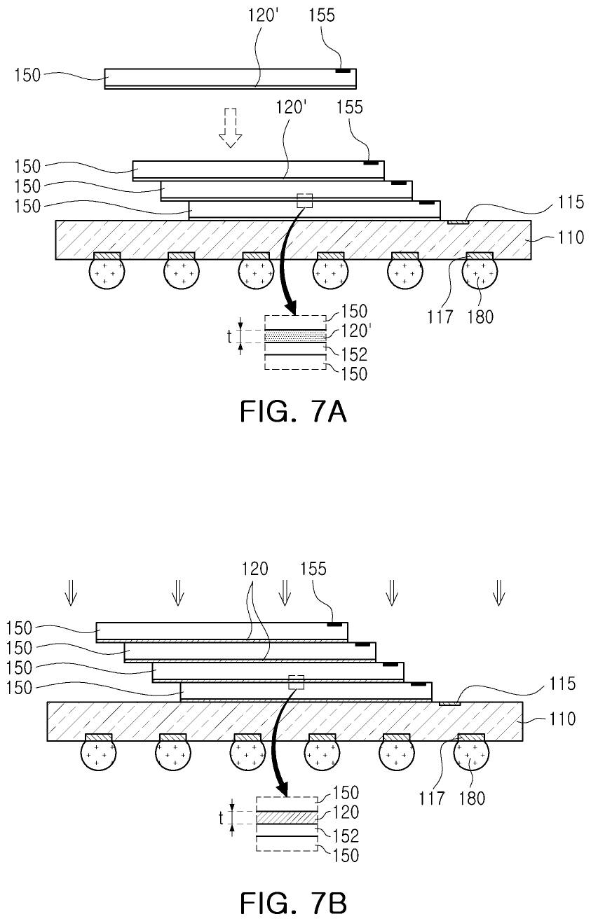

As described above, the semiconductor chip 150 prepared through the process of FIGS. 4A to 4E may be manufactured into the semiconductor package 100 shown in FIGS. 1 and 2 through a subsequent package process (e.g., FIGS. 7A and 7B). FIGS. 7A and 7B are cross-sectional views illustrating major processes (e.g., a chip stacking process) of a method of manufacturing a semiconductor package according to an embodiment of the present inventive concept.

Referring to FIG. 7A, the plurality of semiconductor chips 150 are stacked using the semi-cured adhesive layer 120′.

As described above, the plurality of semiconductor chips 150 may be stacked to be offset in one direction (e.g., the X-direction) so that the chip pads 155 are exposed. In some embodiments, such stacking may be performed by a hot pressing process. After stacking using adhesiveness of the semi-cured adhesive layer 120′, the chip stacks may be pre-fixed by heating to a first temperature in a state in which a constant pressure is applied. When the secondary curing process is performed as a thermal curing process, the modulus of the adhesive layer 120′ semi-cured at the first temperature might not change significantly. For example, the first temperature may be lower than a second temperature for thermal curing. For example, the first temperature for hot pressing may be performed at a temperature in the range of 70° C. to 100° C.

Referring to FIG. 7B, the semi-cured adhesive layer 120′ disposed between the plurality of stacked semiconductor chips 150 is fully cured.

A full curing process may be performed to form a final adhesive layer ensuring a solid bond between semiconductor chips. When the semi-cured adhesive layer 120′ is formed by curing one type of energy-curable portion of the liquid adhesive material LA used in the previous process, the fully cured adhesive layer 120 may be formed by curing the other type of energy-curable portion. When a semi-cured adhesive layer is formed by curing the UV-curable portion using UV light as in the process of FIG. 4D, in this process, the remaining thermo-curable portion may be cured to form a fully cured adhesive layer. In this case, a second temperature for fully curing the semi-cured adhesive layer may be higher than the first temperature for hot pressing. For example, the second temperature may range from 100° C. to 150° C.

A thickness “t” of the fully cured adhesive layer 120 may be similar to or slightly smaller than a thickness t0 of the uncured adhesive layer 120″. Although the reduction varies depending on a component of the liquid adhesive material LA, in particular, a ratio of a solvent, the thickness t of the fully cured adhesive layer 120 may have a thickness in the range of 70% to 95% of the thickness t0 of the uncured adhesive layer 120″. For example, the fully cured adhesive layer 120 may have a thickness of 5 μm or less, and further a thickness of 3 μm or less or 2 μm or less.

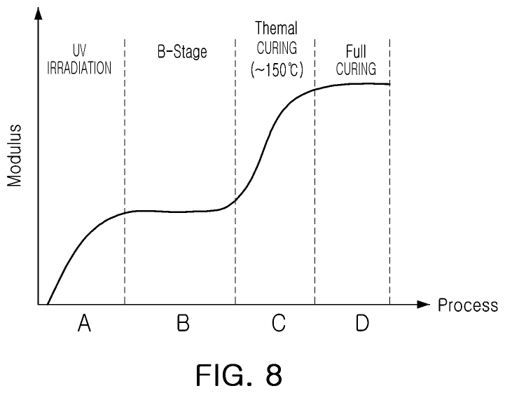

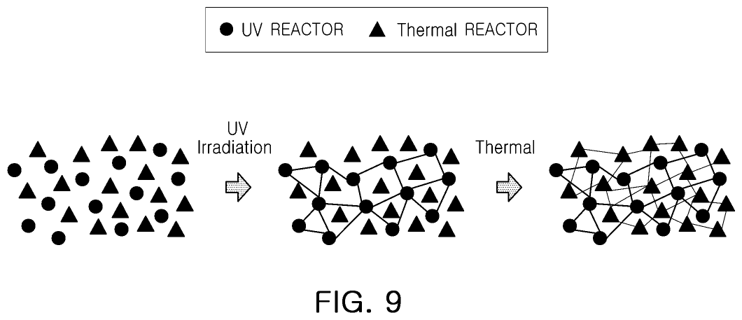

FIG. 8 is a graph illustrating a change in modulus of an adhesive layer in the semiconductor chip and semiconductor package manufacturing process, and FIG. 9 is a schematic diagram illustrating changes in a reactor through primary and secondary curing processes employed in a process of manufacturing a semiconductor package according to an embodiment of the present inventive concept.

Referring to FIGS. 8 and 9, a change in a state of the adhesive layer in the series of manufacturing processes described above is shown. The liquid adhesive material employed in the present embodiment is an adhesive material in which a UV curable composition (symbolized as a circle, “•”) and a thermo-curable composition (symbolized as a triangle, “▴”) are mixed as schematically shown in FIG. 9, and an example in which UV curing process and a thermally curing process are applied as primary and secondary curing processes, respectively, will be described.

The process of forming the adhesive layer according to the present embodiment includes a UV curing process (A) after coating on the rear surface of the wafer. As shown in the second schematic view of FIG. 9, the UV curable composition (•) is cured, but the thermo-curable composition (▴) may remain in an uncured state.

Through this UV curing process, the coated adhesive material (e.g., uncured adhesive layer) may be changed to a B-stage semi-cured adhesive layer, and the modulus thereof may also be increased by the cured portion. This process may be understood with reference to the description of FIG. 4D. The semi-cured adhesive layer may be handleable in a series of subsequent processes (e.g., chip cutting and stacking) (B), in a state of being attached to the wafer.

Subsequently, a thermal curing process (C) after the chip stack may be included. The thermo-curable composition (▴), which has not been cured during the thermal curing process, may also be reacted and cured to provide a fully cured adhesive layer having a high modulus for firmly bonding the stacked chips.

Although the liquid adhesive material includes a photo-curable composition and a thermo-curable composition, the primary curing process may be performed as any one of light energy and thermal energy, and the secondary curing process may be performed as any one of light energy and thermal energy to obtain a semi-cured adhesive layer on the wafer surface. However, in the process of performing the full curing process after the chip stacking, a thermal curing process that makes it easier to apply energy to the adhesive layer may be adopted, and the UV curing process may be adopted in the primary curing process performed at the wafer level.

FIGS. 10 and 11 are side cross-sectional views illustrating semiconductor packages according to various embodiments of the present inventive concept.

Referring to FIG. 10, a semiconductor package 100A, according to the present embodiment, may be understood as having a structure similar to the structure illustrated in FIGS. 1 to 3, except that the semiconductor package 100A includes a chip stack CS' including eight semiconductor chips 150 and further includes a controller 160 configured to control an operation of the semiconductor chips 150 included in the chip stack CS′. The description of the components of the present embodiment may refer to descriptions of the same or similar components of the semiconductor package 100 illustrated in FIGS. 1 to 3, unless otherwise specifically stated.

Also, in the present embodiment, the adhesive layer 120 is formed on lower surfaces of the semiconductor chips 150 constituting the chip stack CS′. As described above, each of the adhesive layers 120 is directly coated on the wafer using a liquid adhesive material, and thus may be implemented in an ultra-thin shape (refer to FIGS. 4B to 4E). The thickness of the adhesive layer 120, according to the present embodiment, may be 5 μm or less. In some embodiments, the thickness of the adhesive layer 120 may be 3 μm or less.

In a stack of eight semiconductor chips 150, as in the present embodiment, when the thickness of each adhesive layer 120 is implemented as 3 μm, an effect of reducing a height (or thickness) of a package of 7×8 μm, for example, 56 μm, compared to the case of using a conventional DAF having a thickness of 10 μm may be expected. As such, the effect of reducing the thickness of the adhesive layer 120, according to the present embodiment, may be expected to increase as the number of stacks increases.

The semiconductor package 100A, according to the present embodiment, may include a controller 160 configured to control operations of semiconductor chips included in the chip stack 101. The controller 160 may be mounted on the package substrate 110. For example, the controller 160 may be mounted on the package substrate 110 in a flip-chip manner. A connection bump 158 may be interposed between the pads 165 of the controller 160 and the pads 115 of the package substrate 110 to electrically connect them to one another. The controller 160 may be electrically connected to the semiconductor chips 150 of the chip stack CS' through the interconnection path 118 provided in the package substrate 110. As described above, the adhesive layer, according to the present embodiment, may be employed in various types of semiconductor packages.

Referring to FIG. 11, a semiconductor package 100B, according to the present embodiment, may be understood as having a structure similar to the structure illustrated in FIGS. 1 to 3, except that different types of semiconductor chips 150a, 150b, and 150c are stacked. Therefore, the description of the components of the present embodiment may refer to descriptions of the same or similar components of the semiconductor package 100 illustrated in FIGS. 1 to 3, unless otherwise specifically stated.

In the present embodiment, the first to third semiconductor chips 150a, 150b, and 150c may have different dimensions from each other, and their stacking methods may be different from each other. The first to third semiconductor chips 150a, 150b, and 150c may be semiconductor chips having different functions, but may be semiconductor chips having different dimensions and performing the same function.

Also, in the present embodiment, the adhesive layer 120 is formed on each of lower surfaces of the first to third semiconductor chips 150a, 150b, and 150c. As described above, each of the adhesive layers 120 is directly coated on the wafer using a liquid adhesive material, and thus may be implemented in an ultra-thin shape (refer to FIGS. 4B to 4E). A thickness of the adhesive layer 120 according to the present embodiment may be 5 μm or less. In some embodiments, the thickness of the adhesive layer 120 may be 3 μm or less. Although the number of stacked semiconductor chips (e.g., two or three) may be relatively small, an effect according to a reduction in the thickness of the adhesive layer 120 may be expected.

By coating a liquid adhesive material on a rear surface of the semiconductor chip at a wafer level, an ultra-thin adhesive layer may be implemented, unlike the conventional film type. In some embodiments, the liquid adhesive material is configured to include a photo-cured portion and a thermo-cured portion, so that different types of energy may be applied to the process of semi-curing from a liquid phase to a B stage and the process of fully curing after chip stacking, thereby increase process efficiency.

While example embodiments of the present disclosure have been shown and described above, it will be apparent to those skilled in the art that modifications and variations could be made without departing from the scope of the present inventive concept.

What is claimed is:

1. A method of manufacturing a semiconductor package, the method comprising:
preparing a wafer having a first surface on which a plurality of semiconductor chips are disposed and a second surface, opposite to the first surface;
grinding the second surface of the wafer;
coating the ground second surface of the wafer with a liquid adhesive material to form an uncured adhesive layer having a thickness of 5 μm or less;
semi-curing the uncured adhesive layer on the wafer;
cutting the wafer so as to separate the plurality of semiconductor chips from one another;
stacking the plurality of semiconductor chips using the semi-cured adhesive layer; and
fully curing the semi-cured adhesive layer between the plurality of stacked semiconductor chips.

2. The method of claim 1, wherein the liquid adhesive material includes a mixture of a photo-curable composition and a thermo-curable composition.

3. The method of claim 2, wherein the photo-curable composition is configured to be cured by ultraviolet (UV) light.

4. The method of claim 2, wherein the photo-curable composition includes an acrylic compound and a photoinitiator.

5. The method of claim 2, wherein the photo-curable composition is configured to cure at a temperature in the range of 100° C. to 150° C.

6. The method of claim 2, wherein the thermo-curable composition includes an epoxy-based compound, a thermosetting agent, and a curing accelerator.

7. The method of claim 1, wherein the stacking of the plurality of semiconductor chips includes a hot pressing process.

8. The method of claim 7, wherein the hot pressing process is performed in a temperature range of 70° C. to 100° C.

9. The method of claim 1, wherein the liquid adhesive material has a viscosity of 2000 cP or less.

10. The method of claim 1, wherein the liquid adhesive material has a viscosity of 10 cP to 1000 cP.

11. The method of claim 10, wherein the uncured adhesive layer has an average thickness in the range of 0.2 μm to 3 μm.

12. The method of claim 1, wherein a thickness variation of the uncured adhesive layer is 10% or less of an average thickness.

13. The method of claim 1, wherein the fully cured adhesive layer has a thickness in the range of 70% to 90% of a thickness of the uncured adhesive layer.

14. A method of manufacturing a semiconductor package, the method comprising:
preparing a wafer having a first surface and a second surface opposite to the first surface, the wafer including a plurality of semiconductor chips disposed on the first surface;
coating the second surface of the wafer with a liquid adhesive material in the range of 10 cP to 2000 cP to form an uncured adhesive layer having a thickness of 5 μm or less;
semi-curing the uncured adhesive layer by applying a first type of energy to the wafer;
cutting the wafer so as to separate the plurality of semiconductor chips from one another;
stacking the plurality of semiconductor chips using the semi-cured adhesive layer; and
fully curing the semi-cured adhesive layer disposed between the plurality of stacked semiconductor chips by applying a second type of energy.

15. The method of claim 14, wherein
the liquid adhesive material includes a photo-curable composition and a thermo-curable composition that are mixed together, and
the first type of energy is light energy and the second type of energy is thermal energy.

16. The method of claim 15, wherein
the stacking of the plurality of semiconductor chips is performed at a first temperature, and the fully curing of the semi-cured adhesive layer is performed at a second temperature that is higher than the first temperature.

17. The method of claim 14, wherein the fully cured adhesive layer has a thickness of 3 μm or less.

18. A method of manufacturing a semiconductor package, the method comprising:
preparing a wafer having a first surface on which a plurality of semiconductor chips are disposed and a second surface, opposite to the first surface;
coating the second surface of the wafer with a liquid adhesive material including an ultraviolet (UV)-curable composition and a thermo-curable composition to form an uncured adhesive layer;
semi-curing the uncured adhesive layer by applying ultraviolet light or heat to the wafer;
cutting the wafer so as to separate the plurality of semiconductor chips from one another;
stacking the plurality of semiconductor chips using the semi-cured adhesive layer; and
fully curing the semi-cured adhesive layer disposed between the plurality of stacked semiconductor chips by applying ultraviolet light, where the semi-curing of the uncured adhesive layer is performed by heat and fully curing the semi-cured adhesive layer disposed between the plurality of stacked semiconductor chips by applying heat, where the semi-curing of the uncured adhesive layer is performed by ultraviolet light.

19. The method of claim 18, wherein
the semi-curing of the uncured adhesive layer is performed using UV light,
the stacking of the plurality of semiconductor chips is performed at a first temperature, and
the fully curing of the semi-cured adhesive layer is performed at a second temperature that is higher than the first temperature.

20. The method of claim 18, wherein
the liquid adhesive material has a viscosity of 10 cP to 1000 cP, and
the uncured adhesive layer has an average thickness in the range of 0.2 μm to 3 μm.
